(19) United States
(12) Patent Application Publication
(10) Pub. No.: US 2016/0178663 A1
(43) Pub. Date: Jun. 23, 2016

(54) FORMED WIRE PROBE INTERCONNECT FOR TEST DIE CONTACTOR

(71) Applicant: INTEL CORPORATION, Santa Clara, CA (US)

(72) Inventors: Mohanraj Prabhugoud, Beaverton, OR (US); Youngseok Oh, Portland, OR (US); Joseph F. Walczyk, Tigard, OR (US); Todd P. Albertson, Warren, OR (US)

(21) Appl. No.: 14/581,508

(22) Filed: Dec. 23, 2014

(51) Int. Cl. G01R 1/04; G01R 1/073; G01R 1/067

(52) U.S. Cl. CPC G01R 1/0416; G01R 1/06794; G01R 1/07328

(57) ABSTRACT

A test die contactor is described with a formed wire probe interconnect. In one example the contactor includes a plurality of wire probes formed to be resilient against longitudinal pressure, a first aligner proximate one end of the wire probes having a first plurality of holes through which the wire probes extend, the first alignment layer to align the wire probes to contact pads of a text fixture, a second aligner proximate the other end of the wire probes having a second plurality of holes through the wire probes extend, the second alignment layer to align the wire probes to contact pads of a device under test, and an insulating layer between the first and the second aligner through which the wire probes extend to hold the wire probes when compressed by longitudinal pressure.

### FIELD

This invention is on the design and development of new second level interconnects for testing packages.

### BACKGROUND

As IC (integrated circuit) dies become smaller, include more transistors, and are packaged in smaller packages, the connection arrays on these packages become smaller. More connections are closer together. For example BGA (Ball Grid Array) packages become smaller and thinner in size with finer pitch arrays. To test these devices, a temporary connection is made to each connector. This temporary connection is used to operate the die at the limit of speed and voltage for purposes of testing. The test is a critical step before the packaged die is attached to a motherboard or socket and used in a device. At the same time the test and the tester may require a significant cost in materials and time.

The tester must be inexpensive and still provide a very reliable, quick, and low force connection to the connection array of the die package. One common tester uses pogo-pins to contact the balls of a BGA device. The pogo pins are spring-based and provide high compliance, durability and reliability. As the number of contacts increases, the number of pogo pins also increases and the pogo pins must be closer together to match the pitch of the BGA.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a partial isometric side view diagram of a contactor according to an embodiment.

FIG. 2 is an exploded isometric view diagram of a contactor according to an embodiment.

FIG. 3A is an exploded isometric view diagram of a socket assembly according to an embodiment.

FIG. 3B is an assembled isometric view diagram of the socket assembly according to an embodiment.

FIG. 4 is a side view diagram of a single wire probe according to an embodiment.

FIG. 5 is a process flow diagram for assembling a contactor according to an embodiment.

FIG. 6 is an exploded isometric view diagram preparing a contactor using an assembly kit according to an embodiment.

FIG. 7 is an isometric view diagram of inserting wire probes into the contactor of FIG. 6 according to an embodiment.

FIG. 8 is an isometric view of placing a cover over the assembly kit of FIG. 7 according to an embodiment.

FIG. 9 is an isometric view of installing spacer on the insulating layer of the assembly kit of FIG. 8 according to an embodiment.

FIG. 10 is an isometric view of installing a second aligner on the assembly kit of FIG. 9 according to an embodiment.

FIG. 11 is a cross-sectional generalized diagram of test equipment suitable for use with the contactor of FIG. 3B according to embodiments.

FIG. 12 is a block diagram of a computing device suitable for use with embodiments.

### DETAILED DESCRIPTION

In some embodiments a simple interconnect is used as a contactor to connect a packaged die to a circuit board. The circuit board conducts input and output signals from a test system to the packaged die through the contactor.

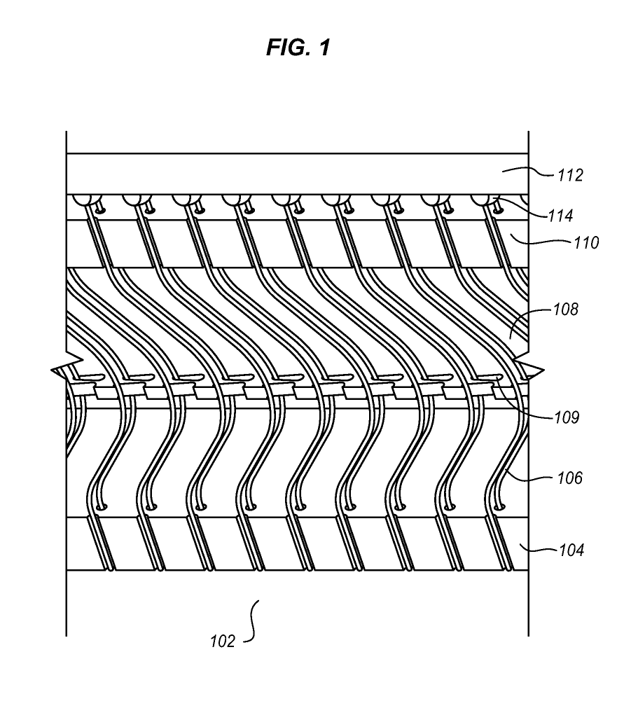

FIG. 1 is a partial isometric side view diagram of a contactor. A PCB (Printed Circuit Board) 102 has traces to and from the contactor and contains any of a variety of other components depending on the nature of the test system and the tests that it performs. A first wire aligner 104 proximate the PCB holds an array of wires 106 in place against contact pads or lands (not shown) on the PCB. The aligner has a hole for each wire and holds each wire in place on a land. The wires make connections to the PCB through these lands and the aligner ensures that the wires contact the appropriate corresponding land.

The wires 106 extend through and from the first aligner 108 through an insulation layer 108 and through holes of a second aligner 110 to contact pads or lands, which in this case are in the form of solder balls 114 but may be any other type of connector of the packaged die 112. The second aligner is proximate the packaged die. The package die will be referred to herein as a DUT (Device Under Test) to distinguish it from other components of the system.

The first and second aligners each have a hole for each wire. These holes hold the wires in alignment with the PCB and DUT respectively but allow for the wire to move vertically as it is compressed. The insulating layer has a slot 109 for each wire. The slots allow the wire to move vertically but also allow the wires to move laterally, with respect to their length, across the slot. The slots have a shape that is longer in one direction than the other orthogonal direction. As shown, the wires 106 are formed with a bend that that forms an arc outward laterally from the two ends. When compressed, the arc of the wire moves further laterally. The slot permits this lateral movement. The slot also prevents the wires from rotating because the arc is captured in the slot.

The PCB may be a separate test board of a test fixture. Multiple contactors may be mounted to this PCB so that multiple packaged dies may be tested simultaneously. In another example, the PCB is within a socket. The socket receives the packaged die for test. There may be multiple sockets attached to a larger main test board. The PCB may be used in another way as a test fixture. The PCB in general applies signals through the wires to connections on the DUT. It also receives signals from the DUT which are then analyzed by the test fixture. A variety of different functional and performance tests may be performed to determine whether the packaged die operates correctly and provides the performance desired.

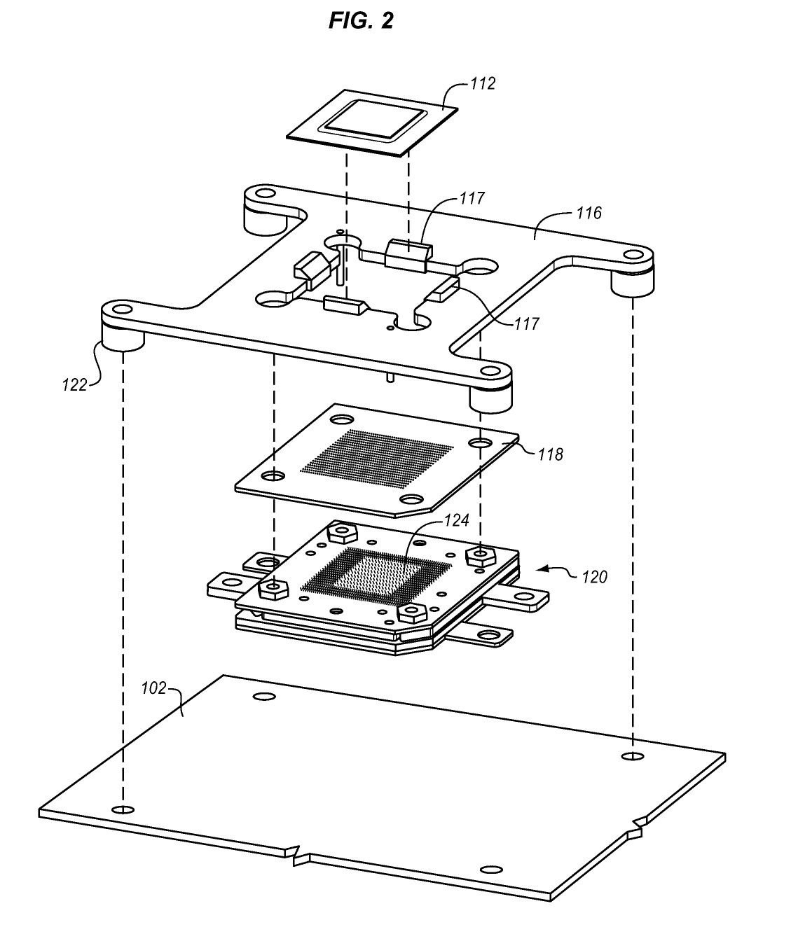

FIG. 2 is an exploded view of the contactor of FIG. 1. The contactor uses a monolithic wire architecture. A DUT (Device Under Test) frame 116 is used to align the contactor to the PCB using alignment pins 122. The alignment pins also each feature a central bore to allow a fastener to run through the bore to the circuit board 102. The fastener may be a screw, bolt or other fastener to secure the frame over the contactor and to the circuit board. The frame also has pins to align the frame with mating holes in the contactor. The DUT frame also has a top socket that provides coarse alignment of the DUT to the wires of the contactor. Tabs 117 or any desired attachment mechanism hold the DUT in place. A ball guide 118 is used to align DUT solder-balls to interconnect. A socket assembly 120 includes the aligners 106, 108, 110 shown in FIG. 1.

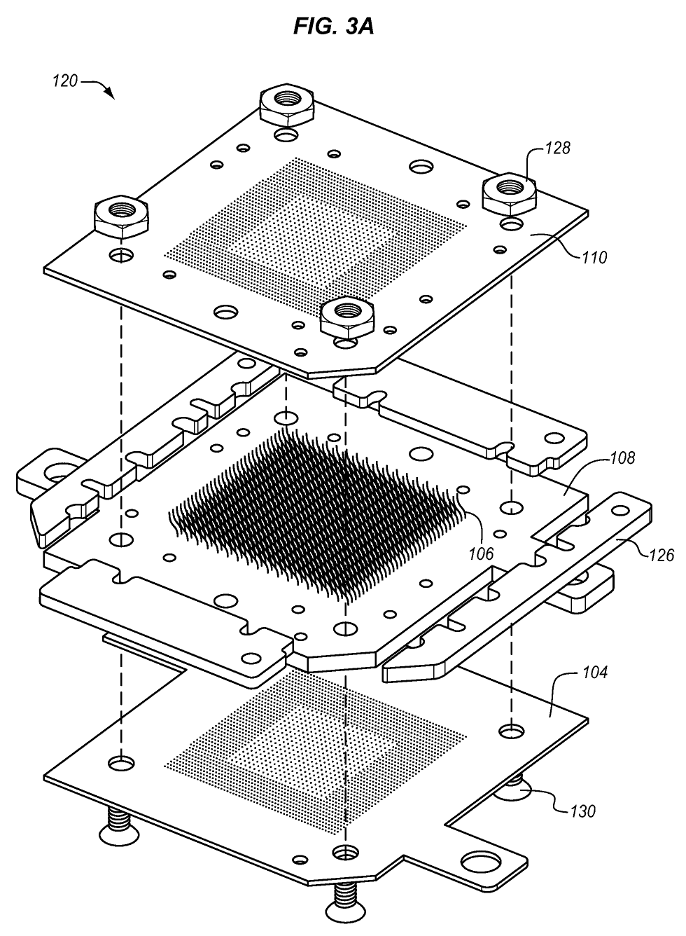

FIG. 3A is an isometric exploded view of the socket assembly 120 of FIG. 2. The main elements are the formed probes 106 used to make the interconnection, an insulation layer 108 and DUT side 110 and PCB side 104 aligners. The number of interconnects or wires 106 per solder-ball 114 may be optimized based on electrical and mechanical requirements of any particular implementation. In the example of FIG. 2, two probes are used for each solder-ball, however one or three or more may be used. The insulation layer has the slots described above that are used to prevent the probes from rotating. The aligners act as guides to hold the wires in place during mechanical compression as a DUT is pressed against the contactor.

Spacers 126 are installed on all four sides of the central insulating layer 108. The spacers establish a distance between the two aligners when the contactor is assembled. The spacers maintain a distance between the insulating layer and the first and second aligner on either side of the insulating layer. The contactor is held together by screws 130 that are secured into nuts 128 attached to the DUT side aligner. Other fasteners may be used instead to suit particular applications and form factors

FIG. 3B is an isometric view of the contactor of FIG. 3A fully assembled. The screws 130 hold the two aligners 104, 110 together with the insulating layer in between and the position of the insulating layer determined by the spacers 126. The wire probes 106 extend through holes in the top and bottom aligners. This allows the wire probes to be compressed between the PCB and the DUT.

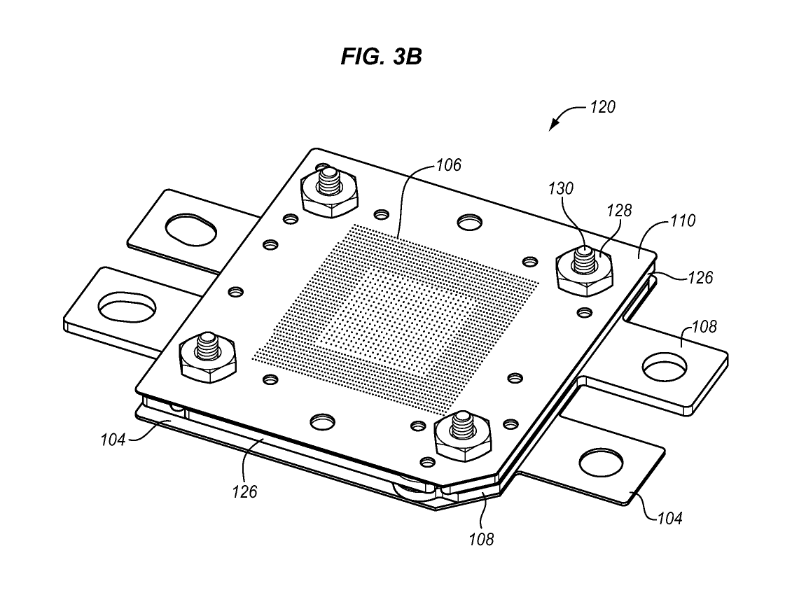

FIG. 4 is a side view diagram of a single wire probe 106 between the PCB 104 and the DUT 112. The wire probe has a bend 107 so that when the DUT is pressed down against the PCB the wire probe bends. This allows the wire probe to maintain contact with the land, pad, or solder ball 114 of the DUT as a leaf spring pressing against the contact on the DUT. The wire probe is formed of a steel, stainless steel, or nickel coated wire that has been pre-bent to have the bend 107 as shown.

The cross section of each of the wire probes may be circular, rectangular, or any other desired shape, depending on the desired characteristics of the particular implementation. For a circular coated wire the interior of the wire provides the spring force against mechanical loads while the coating carries the current. When a rectangular cross-section is used, the middle insulating layer may be removed.

The wire probe has a length shown here in the vertical direction. The pressure is longitudinal against the wire and, due to the bend and the resiliency of the wire material, the wire is resilient against the longitudinal compression shown in FIG. 4. When longitudinally compressed, the wire exerts a corresponding opposite spring force against the compression. The wire has inherent mechanical and electrical load members that provide desired interconnect characteristics. The wire geometry may be optimized to provide the desired mechanical compliance, impedance, inductance, current carrying ability, contact resistance, etc. The wires may first be formed and then integrated into the socket assembly.

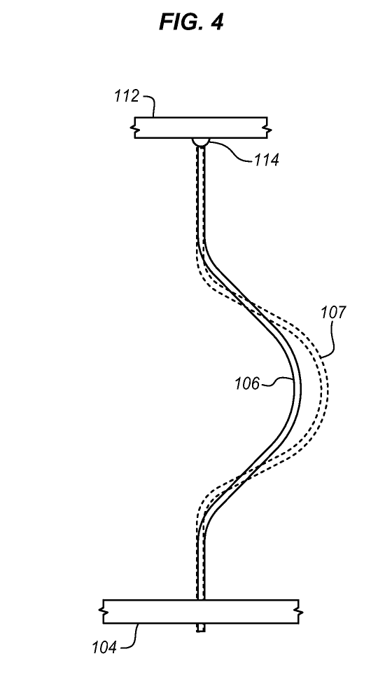

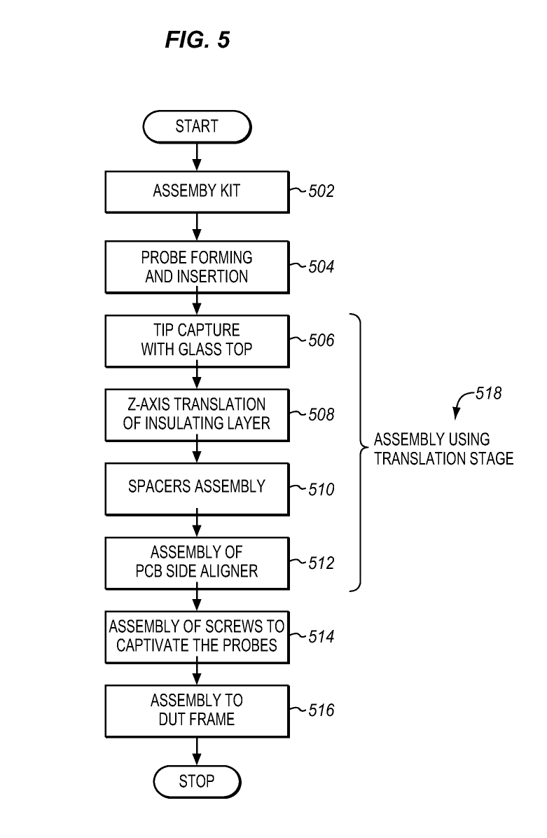

FIG. 5 is a process flow diagram for assembling a contactor as described and shown above. The process begins at start and then with an assembly kit. The assembly kit 610 is shown in FIG. 6. FIG. 6 is an exploded isometric diagram of preparing a fixture before populating the contactor with formed interconnects. The preparation is done for each time there is a new DUT with a new footprint of contacts.

A base fixture 602 of the assembly kit may be made of rigid material such as aluminum and houses a stencil 604 that is covered by a tacky adhesive, thermal grease or any other desired light adhesive may be used. The stencil material may be formed of a dimensionally stable material such as a nickel-iron alloy like Invar. The DUT side aligner 110 as shown in FIGS. 1 and 2 is used to hold the wire probes in place so that a dielectric material that does not change shape or size when the wire probes are heated by electrical current is preferred. A stable and dielectric material such as a ceramic, for example, alumina or aluminum oxide may be used. The DUT side aligner has an array 606 of holes that are tightly toleranced to align with the contact pads on the DUT.

The insulating layer 108 also has slots 109 for each of the wire probes, however, the alignment is not as precise. The insulating layer is used to prevent the probes from rotating while allowing the probes to be compressed as shown in FIG. 4. The slots allow for some movement but only in the direction of the slot. This helps to prevent rotation. The insulating layer may also be made from a ceramic or from a polyimide material and has an integral frame around its perimeter to stiffen it.

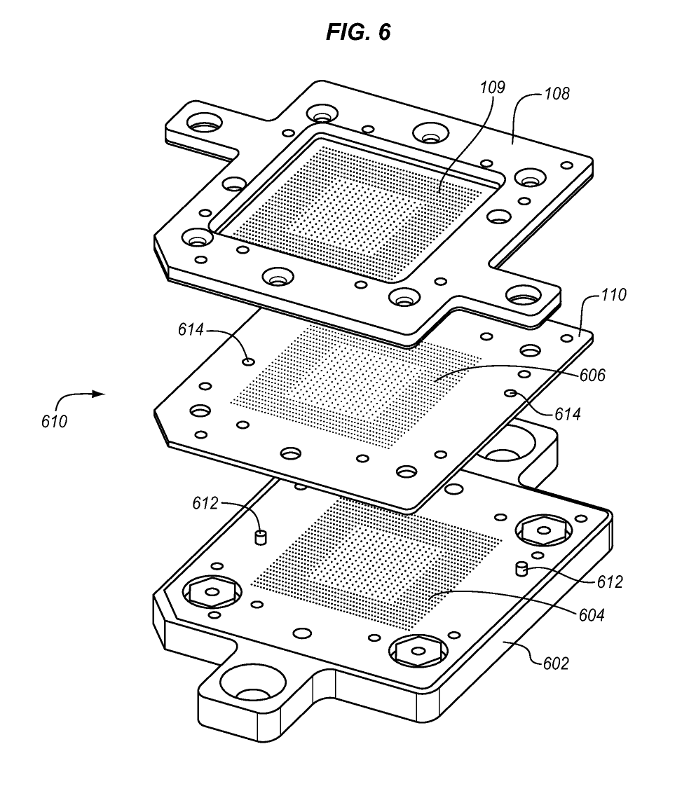

All the components of the assembly kit of FIG. 6 are assembled together and aligned using, for example a microscope. The base fixture 602 also has alignment pins 612 that mate with corresponding holes 614 in the insulating layer to provide a rough alignment before the more precise microscope or similar alignment. Other types of alignment features, such as tabs, grooves, fingers, slots, etc. may be used in addition to or instead of the pins, depending on the particular implementation. The insulating layer is 108 then fastened to the base fixture 602 using screws, clamps, or some other attachment. The assembled assembly kit is shown in FIG. 7 in which like reference numbers refer to the same system.

At 504 the wire probes are inserted into the assembly kit. The probes may be individually placed in each slot of the insulating layer 108 and then through the corresponding DUT side aligner hole. The probes are pushed into the stencil and are held in place by the adhesive layer. FIG. 7 shows a wire probe 622 (greatly enlarged), held by a tool 620 for insertion into a slot in the insulating layer of the assembled kit 610.

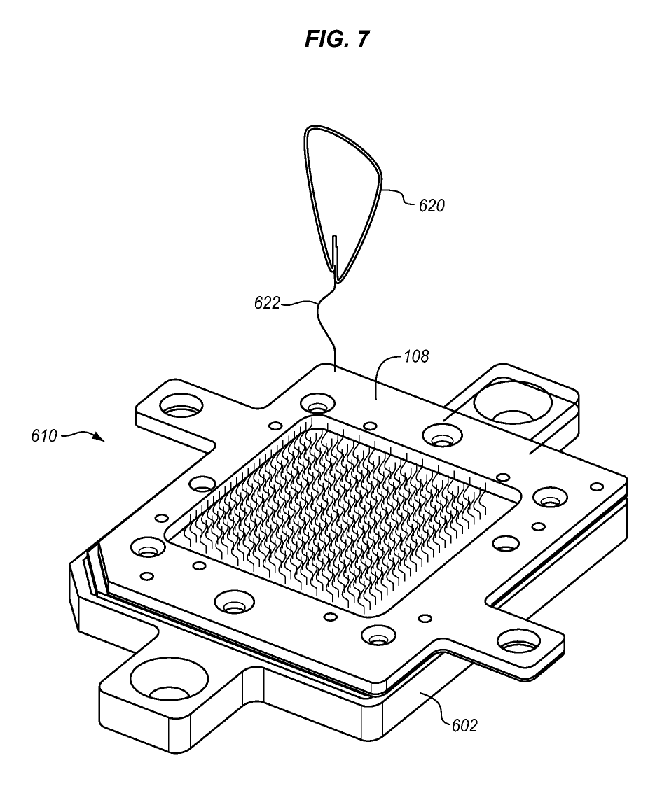

At 506 after all the probes are placed into the assembly kit, the tips of all of the probes are captured using a cover 624. In some embodiments a glass top sheet is temporarily placed over the insulating layer to capture the probe tips as shown in FIG. 8. The glass sheet may be screwed on or attached in some other way. Alternatively, the weight of the glass sheet may be used to secure it in place.

At 508 the insulating layer assembly is translated up or down or both along the wire probes. This moves the insulating layer between the base fixture and the insulating layer. This movement rotates any wire probes by moving the respective slot across each probe. The probes are then in alignment and the insulating layer may stop in a location that prevents any further rotation of the probes. This location may be the location as shown in FIG. 1 in which a slot is across a part of the bend or arc in the probe wires, If the probe wires rotate, then the movement is stopped by the sides of the slots. A special or purpose built translation stage may be used for this purpose.

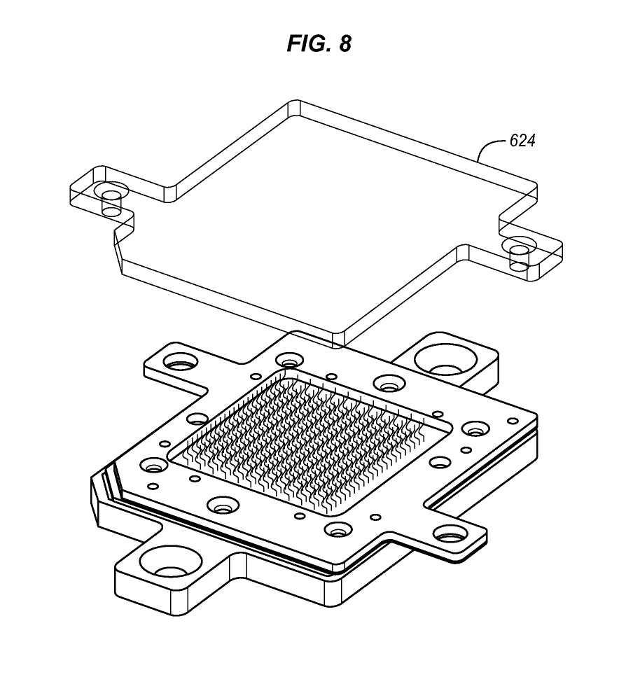

At 510 spacers 126 are installed on all four side of the insulating layer. This is shown in the diagram of FIG. 9. In this example, the spacers may be inserted laterally against the sides of the insulating layer. The spacers hold the insulating in a specific location with respect to the DUT side aligner and later determine the distance not only from the DUT side aligner but also the distance from the PCB side aligner. This location may be the location as shown in FIG. 1. The spacers may be made of any desired stable stiff material, such as a polymer or thermoplastic, for example an acetal homopolymer, such as Delrin® or PEEK™. With the wire probes properly positioned and the insulating layer secured by the spacers, the glass cover 624 may be removed.

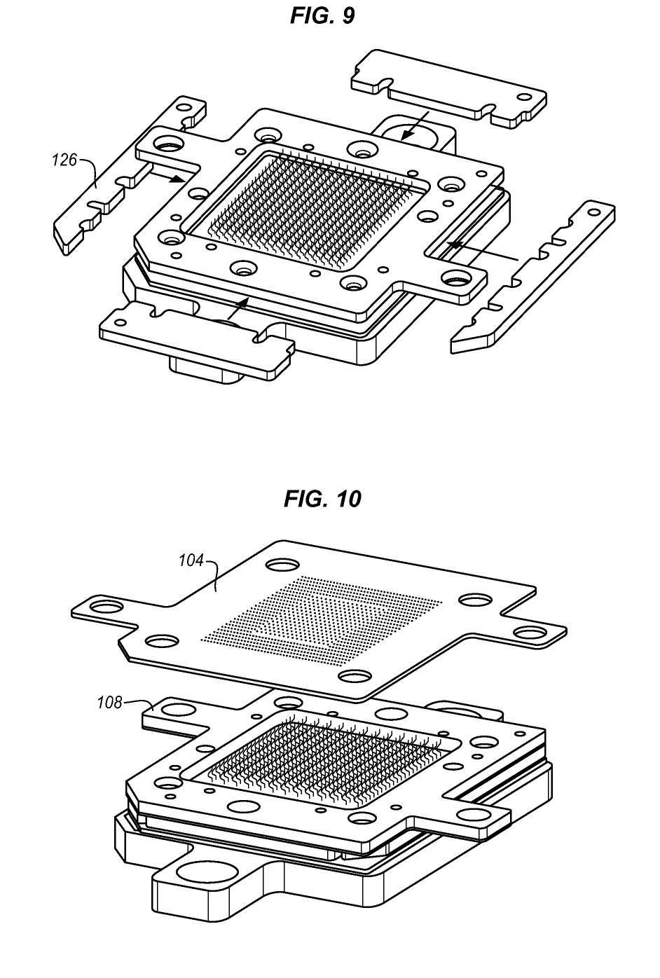

At 512, the PCB side aligner 104 is placed over the insulating layer after the glass cover is removed as shown in FIG. 10. The PCB side aligner may be formed of ceramic and is similar to the DUT side aligner 110. Holes in the PCB side aligner may be made to have a larger diameter to allow the probes to tilt under compression. The PCB side aligner is aligned so that each probe is inserted through a respective hole in the aligner.

At 514, after the PCB side aligner is in position, screws 130 or another fastener may be used to hold all of the components together as shown in FIG. 3B. In the illustrated embodiment, there are nuts 128 fastened to the DUT side aligner and the heads of the screws 130 are pressed against the PCB side aligner. The screws hold the two aligners against each other and the insulating layer is positioned between these two by the spacers 126. The wire probes are captured by the holes in the two aligners and prevented from rotating by the slots in the insulating layer. The DUT side aligner may have an rectangular opening like the insulating layer. The may further help to prevent the probe wires from rotating.

At 516, the base fixture 602 is removed leaving only the two aligners and the insulating layer. The completed contactor is shown in FIG. 3B and may be integrated with an IC socket or with any other test fixture equipment depending on the particular implementation. The socket assembly is aligned to the DUT frame 116 using alignment features such as pins or tabs. The socket assembly is aligned to a pre-determined position on the PCB 102 using an alignment feature such as pins 122 in the DUT frame 116. The DUT frame may then be attached over the assembled contactor to hold the contactor in place. The contactor is aligned so that the probe wires connect with corresponding contacts on the PCB. An opening in the DUT frame provides alignment between the contactor and the DUT 112. In addition, the DUT frame preloads the contactor or socket to the PCB when it is attached to the PCB over the contactor.

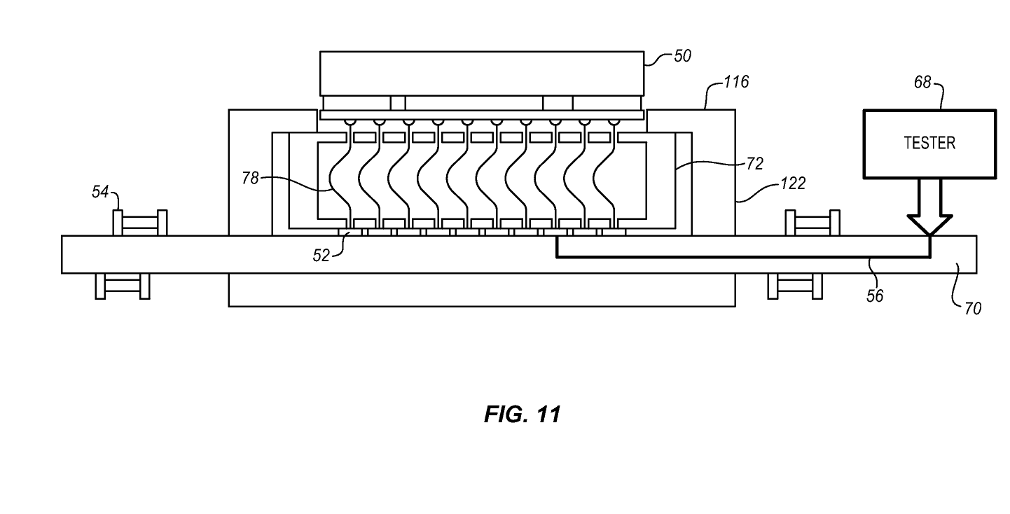

FIG. 11 is an example of testing equipment capable of using the formed test probes 78 and contactor to test and sort dies 50 of various types. The contactor 72 has a contact pad array formed of the test probes as described above. The test probes are arranged in a pattern to match with test sites on the device under test 50, such as a packaged die. The wire test probes 78 each have a lower end configured and arranged for mating with a corresponding test pad 52 on a PCB 70. The test probes 78 have a pitch that matches the pitch of the test pads 52 on the PCB 50 due to the PCB side aligner 109.

The DUT frame 116 is mounted over the contactor 72 using alignment pins 122 and carries the DUT 50. The DUT frame compresses the test probes 78 of the contact array on to a connection pad of a testing PCB (Printed Circuit Board) 70. Additional mounting rings, holders, space transformers, brackets, and other structures may be used to hold the assembly in place and secure the DUT to the test contacts. The PCB then connects to ATE (Automated Test Equipment) 68 through a cable, routing layers, or any other desired connection type 56. The ATE drives the test and measures the results through the test probes. Various passives 54 condition power and data signal lines to resemble an operational installation or to improve test results.

The example of FIG. 11 is a generalized diagram of test equipment to show a context for use of the contactor with test probes produced as described above. The contactor may be used in many other types of test equipment, depending on the nature of the DUT and the type of test to be performed. The contactor may also be used to test packages with one or more dies in stacked or side-by-side configurations.

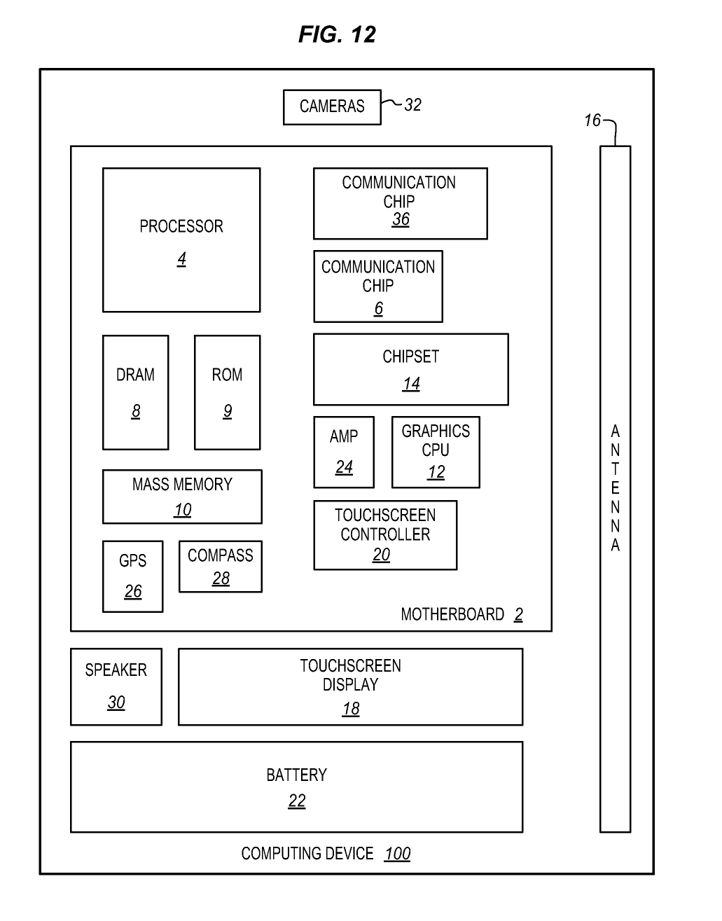

FIG. 12 illustrates a computing device 100 in accordance with one implementation of the invention. The computing device 100 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 100 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components.

The communication chip 6 enables wireless and/or wired communications for the transfer of data to and from the computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 4 of the computing device 100 includes an integrated circuit die packaged within the processor 4 In some implementations of the invention, the integrated circuit die of the processor, memory devices, communication devices, or other components include one or more packaged dies and the packages are tested using a contactor as described above. The term “processor” may refer to any device or portion of a device that processes electronic data from registers and/or memory to transform that electronic data into other electronic data that may be stored in registers and/or memory.

In various implementations, the computing device 100 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, a digital video recorder, a wearable device, or a node for an Internet of Things (IoT). In further implementations, the computing device 100 may be any other electronic device that processes data.

Embodiments may be adapted to be used with a variety of different probe wires, probe heads, and devices under test using various types of testing equipment for different implementations. References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the specific location of elements as shown and described herein may be changed and are not limited to what is shown. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a contactor that includes a plurality of wire probes formed to be resilient against longitudinal pressure, a first aligner proximate one end of the wire probes having a first plurality of holes through which the wire probes extend, the first alignment layer to align the wire probes to contact pads of a text fixture, a second aligner proximate the other end of the wire probes having a second plurality of holes through the wire probes extend, the second alignment layer to align the wire probes to contact pads of a device under test, and an insulating layer between the first and the second aligner through which the wire probes extend to hold the wire probes when compressed by longitudinal pressure.

Further embodiments include a plurality of spacers attached to the insulating layer to establish a distance between the first and second aligners and maintain a distance between the insulating layer and the first and second aligners.

In further embodiments the first and second aligner are dielectric.

In further embodiments the dielectric is ceramic.

In further embodiments the first and second aligners are attached together.

In further embodiments the insulating layer has a plurality of slots through which the wire probes extend to prevent the wire probes from rotating.

In further embodiments the second plurality of holes have a rectangular cross-section to further prevent the wire probes from rotating.

In further embodiments the wire probes are formed with a bend that forms an arc and wherein the insulating layer has a plurality of slots through which the arcs of the wires extend allowing the wire probes to move longitudinally through the slots.

In further embodiments the wire probes have either a circular or rectangular cross-section and wherein the rectangular cross-section wire probes do not have a middle insulating layer.

Further embodiments include a frame having alignment features to align the second aligner to the frame and pins to align the frame to a circuit board, the frame attaching the first and second aligner to the circuit board.

In further embodiments the frame includes a socket to hold the device under test in contact with the wire probes.

Some embodiments pertain to a packaged integrated circuit die test system that includes a circuit board having a contact array and a connector to automated test equipment, and contactor mounted to the circuit board and electrically connected to the circuit board, the contactor having a plurality of wire probes formed to be resilient against longitudinal pressure, a first aligner proximate one end of the wire probes having a first plurality of holes through which the wire probes extend, the first alignment layer to align the wire probes to contact pads of a text fixture, a second aligner proximate the other end of the wire probes having a second plurality of holes through the wire probes extend, the second alignment layer to align the wire probes to contact pads of a device under test, and an insulating layer between the first and the second aligner through which the wire probes extend to hold the wire probes when compressed by longitudinal pressure.

In further embodiments the contactor further comprises a frame having alignment features to align the second aligner to the frame and pins to align the frame to the circuit board, the frame attaching the first and second aligner to the circuit board.

Some embodiments pertain to a method that includes inserting a first end of a plurality of probe wires each through a respective hole of an insulating layer and of a first alignment layer into an adhesive, the wire probes to connect contact pads of a device under test to contact pads of a test fixture, placing a top over a second end of the inserted probe wires to prevent the probe wires from moving away from the adhesive, translating the insulation layer away from the first alignment layer and the first ends of the probe wires, removing the top and placing the second ends of the inserted probe wires through holes of a second aligner so that the second ends are held by the second aligner, and fastening the second aligner to the first aligner.

Further embodiments include applying spacers to the insulating layer before fastening, the spacers to maintain a distance between the insulating layer and the first and second aligners when the first and second aligners are fastened together.

In further embodiments the wire probes are formed with an arc-shaped bend, wherein the holes of the insulation layer are elongated as slots, and wherein translating the insulation layer comprises moving the insulation layer until the bends are aligned with the slots.

In further embodiments translating comprises rotating the wire probes using the slots so that the arc-shaped bends of the wire probes are aligned.

In further embodiments the adhesive is on a base fixture under the first aligner, the method further comprising removing the base fixture after removing the top.

Further embodiments include attaching the fastened second and first aligner to a circuit board by attaching a frame over the second and the first aligner and to the circuit board.

Further embodiments include attaching a device under test to the frame.

What is claimed is:

1. A contactor to electrically connect an integrated circuit die to a test fixture, the contactor comprising:
a plurality of wire probes formed to be resilient against longitudinal pressure;
a first aligner proximate one end of the wire probes having a first plurality of holes through which the wire probes extend, the first alignment layer to align the wire probes to contact pads of a text fixture;
a second aligner proximate the other end of the wire probes having a second plurality of holes through the wire probes extend, the second alignment layer to align the wire probes to contact pads of a device under test; and
an insulating layer between the first and the second aligner through which the wire probes extend to hold the wire probes when compressed by longitudinal pressure. .

2. The contactor of claim 1, further comprising a plurality of spacers attached to the insulating layer to establish a distance between the first and second aligners and maintain a distance between the insulating layer and the first and second aligners.

3. The contactor of claim 1, wherein the first and second aligner are dielectric.

4. The contactor of claim 3, wherein the dielectric is ceramic.

5. The contactor of claim 1, wherein the first and second aligners are attached together.

6. The contactor of claim 1, wherein the insulating layer has a plurality of slots through which the wire probes extend to prevent the wire probes from rotating.

7. The contactor of claim 1, wherein the second plurality of holes have a rectangular cross-section to further prevent the wire probes from rotating.

8. The contactor of claim 1, wherein the wire probes are formed with a bend that forms an arc and wherein the insulating layer has a plurality of slots through which the arcs of the wires extend allowing the wire probes to move longitudinally through the slots.

9. The contactor of claim 1, wherein the wire probes have either a circular or rectangular cross-section and wherein the rectangular cross-section wire probes do not have a middle insulating layer.

10. The contactor of claim 1, further comprising a frame having alignment features to align the second aligner to the frame and pins to align the frame to a circuit board, the frame attaching the first and second aligner to the circuit board.

11. The contactor of claim 10, wherein the frame includes a socket to hold the device under test in contact with the wire probes.

12. A packaged integrated circuit die test system comprising:
a circuit board having a contact array and a connector to automated test equipment; and
contactor mounted to the circuit board and electrically connected to the circuit board, the contactor having a plurality of wire probes formed to be resilient against longitudinal pressure, a first aligner proximate one end of the wire probes having a first plurality of holes through which the wire probes extend, the first alignment layer to align the wire probes to contact pads of a text fixture, a second aligner proximate the other end of the wire probes having a second plurality of holes through the wire probes extend, the second alignment layer to align the wire probes to contact pads of a device under test, and an insulating layer between the first and the second aligner through which the wire probes extend to hold the wire probes when compressed by longitudinal pressure.

13. The system of claim 12, wherein the contactor further comprises a frame having alignment features to align the second aligner to the frame and pins to align the frame to the circuit board, the frame attaching the first and second aligner to the circuit board.

14. A method comprising:
inserting a first end of a plurality of probe wires each through a respective hole of an insulating layer and of a first alignment layer into an adhesive, the wire probes to connect contact pads of a device under test to contact pads of a test fixture;
placing a top over a second end of the inserted probe wires to prevent the probe wires from moving away from the adhesive;
translating the insulation layer away from the first alignment layer and the first ends of the probe wires;
removing the top and placing the second ends of the inserted probe wires through holes of a second aligner so that the second ends are held by the second aligner; and
fastening the second aligner to the first aligner.

15. The method of claim 14, further comprising applying spacers to the insulating layer before fastening, the spacers to maintain a distance between the insulating layer and the first and second aligners when the first and second aligners are fastened together.

16. The method of claim 14, wherein the wire probes are formed with an arc-shaped bend, wherein the holes of the insulation layer are elongated as slots, and wherein translating the insulation layer comprises moving the insulation layer until the bends are aligned with the slots.

17. The method of claim 16, wherein translating comprises rotating the wire probes using the slots so that the arc-shaped bends of the wire probes are aligned.

18. The method of claim 14, wherein the adhesive is on a base fixture under the first aligner, the method further comprising removing the base fixture after removing the top.

19. The method of claim 14, further comprising attaching the fastened second and first aligner to a circuit board by attaching a frame over the second and the first aligner and to the circuit board.

20. The method of claim 19, further comprising attaching a device under test to the frame.
